(19) United States
(12) Patent Application Publication
(10) Pub. No.: US 2011/0020736 A1
(43) Pub. Date: Jan. 27, 2011

(54) METHOD OF PRODUCING HOLOGRAPHIC IMAGES OF IC TOPOLOGIES

(75) Inventors: Vadim Israilovich Rakhovskiy, Moscow (RU); Michael Vladimirovich Borisov, Moscow (RU); Alexey Stanislavovich Shamaev, Moscow (RU); Dmitriy Anatolievich Chelubeev, Dmitrov (RU); Alexander Alexandrovich Gavrikov, Kemerovo (RU); Dmitrij Urievich Knyazkov, Moscow (RU)

Correspondence Address: RATNERPRESTIA, P.O. BOX 980, VALLEY FORGE, PA, 19482, US

(73) Assignee: Vadim Israilovich Rakhovskiy, Moscow (RU)

(21) Appl. No.: 12/836,670

(22) Filed: Jul. 15, 2010

(30) Foreign Application Priority Data
Jul. 22, 2009 (RU) 2009128066/28

(51) Int. Cl. G03F 1/00

(52) U.S. Cl. 430/2

(57) ABSTRACT

The invention is aimed at producing a layout with high technological characteristics including a reduction of departure of an obtained layout geometry from a given layout geometry, an increase of a contrast of the obtained layout and a decrease of noise levels in illuminated and not illuminated areas of the layout. This is achieved by converting an initial layout image into a digital pattern; recording an amplitude and phase information, which characterizes each dot of the pattern as an extended or a point radiator; computing a diffraction picture in each dot of the future hologram created from the whole set of radiators—elements of this pattern and its interference with a calculated reference wavefront; employing the obtained result for hologram creation; and obtaining the hologram as a set of discrete elements, which differ by their optical properties.

### FIELD OF THE INVENTION

The invention relates to the microlithography field and can be embodied in industry for example in the process of manufacturing ICs, binary holograms or structures having preprogrammed topography with a submicron resolution for producing hologram masks. It can be used in the optical industry to manufacture focusing, diverging and correcting optical elements, for example, kinoforms, in devices for optical control of aspherical surface shapes, such as hologram compensators.

### BACKGROUND

Design of ICs with a characteristic element dimension of 0.1-0.01 micron is a major promising direction of the current microelectronics development. The high-precision technology (having submicron and micron tolerances) of making precise forms with a 3D relief can find industrial application, for example, in development of a mass technology of producing micro-robotic parts, high-resolution elements of diffraction and Fresnel optics, as well as in other technical fields where it is necessary to get a 3D IC layout of a specified depth with a high resolution of its structures in a functional layer of a device. The latter can be used for instance for a production of printing plates for making banknotes and other securities.

Further progress of the up-to-date microelectronics strongly depends on the microlithography process resolution that defines the development level of a majority of current science and technology fields. The microlithography involves coating a solid body (usually a substrate made of a semiconductor material) with a layer of a material sensitive to the used radiant flow, optical radiation or electron beams. More often a photoresist layer is used for this purpose. Exposure of the photoresist through a pattern, usually called “a mask”, makes it possible to produce an image on the photoresist that corresponds to the specified topology for example the topology of a certain layer of the IC, which is being produced.

The positioning accuracy of the best projection scanning systems (steppers) made by the Dutch ASM-Lithography company, which is a leader in this field of microelectronics technology equipment, reaches 10 nm that is explicitly insufficient for making VLSI ICs with a characteristic element dimension of 20-30 nm. The gap between of the steppers' abilities and the industry demand is intrinsic because 3-5 years are required to develop a stepper for submicron technologies and its cost in case of a mass production is 10-70 million dollars depending on the resolution provided, let alone the development cost that amounts to many hundreds of million US dollars.

At present the photomicrolithography (or photolithography) is most widely used in the industry. The resolution Δx that it provides is determined by the wavelength λ of the radiation used and the numerical aperture NA of the projection system: Δx=κ₁λ/NA (W. Moro “Microlithography”: in 2 parts. Part 1: Transl. from English—Moscow. Mir, 1990, p. 478 [1]). Such dependence reasonably encouraged developers to use more and more shorter wavelength radiation sources and more and more larger aperture projection systems. As a result for the last 40 years the industrial projection photolithography has switched from using mercury lamps with a characteristic radiation wavelength of 330-400 nm to excimer lasers with an operating wavelength of 193 nm and even 157 nm. Projection lens of modern steppers have reached 600-700 mm in diameter that causes a fast increase of the stepper cost.

The resolution increase results in a sharp decrease of the focusing depth ΔF since ΔF=±λ/2(NA)² [1, p. 478] that causes a reduction of the output rate and a drastic complication of the focusing system of giant projection lens, that again means an increase of steppers' cost. Moreover, side effects limit using the aperture of such lens at operation with the maximum resolution provided by the lens.

In the process of the projected photolithography development the minimum dimension of projected parts was decreasing at an average of 30% every two years, this allowed doubling the quantity of transistors in an IC every 18 months (Moore's Law). Nowadays “0.065 micron technology” is used in the industry, which makes it possible to print parts with a resolution of 65 nm, meantime, according to experts' opinion, the next milestone is a development of projection systems and radiation sources providing reliable resolution at a level of 22 nm. It will require a switch to extreme ultraviolet (EUV) sources or even to soft X-ray radiation. At present intensive experiments with λ=13.4 nm microlithography devices are being conducted. The first such equipment, as was announced at INTEL Developers Forum (the INTEL company is the world leader in VLSI IC production), had been already created and in 2002 it was used to produce transistors with a characteristic dimension of 50 nm. However, experts think that the cost of such stepper, even in case of its volume production, would reach USD70 million, and, according to most optimistic estimates, 3-5 years will be required to master technology of a mass production of microprocessors having characteristic element dimensions at a level of 30 nm.

One of the most critical constraints of the photolithography application is related to diffraction from edges of the mask (diffraction from edges of the screen) used for getting a desired projecting image on the photoresist surface. As the monochromatism of the used radiation increases, the above effect deteriorates the quality of the received image due to occurrence of diffraction maximums placed at distances of the A order from the center of the projected line. If one takes into account that the leading manufacturers currently use a laser radiation with wavelength λ=193 nm and even less (in experimental steppers), it becomes clear how significant can be the resolution constraint caused by the diffraction on the mask edges.

Thus existing projection devices designed to generate images on a light sensitive layer have a number of essential drawbacks:

1) Fundamental difficulties of combining a high resolution and a considerable depth of focus in one device

2 ) Considerable complication of the design and technology of projection devices as the wavelength of the radiation used to project an image onto a photoresist becomes shorter

3 ) Drastic complication of the optical system and the technology of making a projected object (a mask) as the wavelength used for projection becomes shorter

4) Significant rise in technology and equipment prices as the integration scale in the manufactured products grows

5) Extremely low technological flexibility of the production process and a very high cost of its modification

6) Unfeasibility in principle of making a diversified manufacture, i.e. a fabrication of various ICs on the same substrate during the common technological process

There is known a method of producing a binary hologram by generating a plurality of transmission areas at specified locations or earlier calculated positions on a film, which is opaque to the used radiation, in such a way that when illuminated these transmission areas make it possible to produce a holographic image at a predetermined distance from these areas (L. M. Soroko “The Fundamentals of Holography and Coherent Optics”.—Moscow, Nauka, 1971, p. 420-434 [2]). This monograph considers a possibility of producing a “numeric” hologram, also called a “synthetic”, “artificial” or “binary” hologram, and sets forth the theory with conciseness and clearness peculiar to mathematic descriptions. However, the known method of making binary holograms, where the image of the transmission areas is produced for example by graphical means and then photographed with a significant reduction, does not provide a desired image quality and high resolution, primarily because of an insufficient accuracy of its production and an insufficient number of the transmission areas used.

There is known a method of producing an image on a sensitive to the used radiation material by a hologram. In this method on the surface of the sensitive to the used radiation material exposure spots are generated by imaging at least one hologram placed in front of the radiation sensitive material (GB 1331076 A, publ. Sep. 19, 1973 [3]). However, the known method of using a hologram to provide an image on the material sensitive to the used radiation does not allow for producing high quality images due to mutual overlapping of a plurality of diffraction orders, and for obtaining a high resolution because of impossibility of using short-wave radiation sources. Moreover, the main objective of this method was to provide an effective control of visually checked marks.

The nearest to the claimed method by its technical gist and obtained results is a method of producing a binary hologram described in RU 2262126 [4]. According to the description, in a film of a material, which is opaque to the radiation used to restore the image, a plurality of transmission areas is created in compliance with specified or calculated sizes and positions. Previously on the sensitive to the used radiation material, which is placed on the film of an opaque material, an image of the mentioned plurality of the transmission areas is formed. The image of each of these transmission areas is created by forming a cumulative overlap area of exposure spots, wherein each exposure spot ensures the radiation dose received by the radiation sensitive material less than Eₜₕᵣₑₛₕ, where Eₜₕᵣₑₛₕ is a radiation dose threshold equal to the sensitivity threshold of the sensitive to the used radiation material, and a radiation dose received by the sensitive to the used radiation material in each cumulative overlap area of the exposure spots is equal or exceeds Eₜₕᵣₑₛₕ. The exposure spots are generated by a two-dimensional radiator array placed in front of the surface of the sensitive to the used radiation material. Each radiator is capable of controlling its radiation intensity and has, at least, one element interconnected with the radiation source to generate a radiation beam of specified dimensions and a cross-section shape In order to get each of the cumulative exposure spot overlapping areas, before exposing at least one exposure spot of those exposure spots, which form the given cumulative overlap area, the radiator array or/and the sensitive to the radiation material are moved in the plane parallel to the surface of the sensitive to the used radiation material either in one and the same direction or in two mutually perpendicular directions. Then an appropriate procedure is used to form the mentioned set of transmission areas in the film of the material that is opaque to the used radiation.

The drawback of the known method is a restriction imposed on the structure of the obtained binary hologram: the formed elementary transmission areas can be located only as a regular grid with pitches not less than pitches of radiator locations in the array. Accordingly it constrains ability to effect parameters of a holographic image by modification of the hologram structure. Besides, the known method does not take into account a possibility of making a hologram as a set of holes in a medium transparent for the radiation, which forms a holographic image, or as alternate recesses in the medium that reflects this radiation, or as a combination of parts of these two variants. It does not provide a maximum employment of opportunities granted by the holographic method of producing high-quality images. Besides, the known method does not consider possibilities of making corrections of the hologram structure before its fabrication: these corrections account physical conditions of making the holographic image and are performed in order to provide the highest possible quality of the latter.

### SUMMARY OF THE INVENTION

The method of generating holographic layout images claimed in the invention aimed at obtaining a layout with high technological parameters, including a reduction of a deviation of geometry of the obtained layout from that of the required one, an increase of the contrast and a decrease of the noise level in exposed and not exposed areas of the layout.

The result is obtained by transforming the initial layout image into a digital pattern, recording the amplitude and phase information, which characterizes each dot of the pattern as an extended or point radiator and calculating the parameters necessary for the recording radiation beam. To do so, elements of the digital pattern of the layout image are transformed into a digital pattern of the future hologram. A diffraction picture in each dot of the future hologram created by the whole set of radiators—elements of the digital pattern of the layout image is determined and then an interference picture is calculated. This interference picture is a result of interaction of the calculated diffraction picture and the calculated wave front from a virtual reference point or extended radiation source identical to the real wave front of the source, which will be used for generation of the holographic image of the layout. The obtained result is used as a signal for modulating the radiation beam in order to get a diffraction structure of the hologram on its carrier plate, and then the hologram is produced as a set of discrete elements with different optical characteristics.

The result is also obtained by making the discrete elements as holes in an opaque or transparent medium.

The result is also obtained by making the holes of the same dimensions and shapes.

The result is also obtained by making the holes of different dimensions but identical shapes.

The result is also obtained by placing the holes over a uniform or nonuniform grid.

The result is also obtained by implementing the set of the discrete elements as alternate recesses in the reflecting medium or as alternate reflecting and nonreflecting elements.

The result is also obtained by making the recesses in the reflecting medium or the reflecting elements of the same dimensions and shapes

The result is also obtained by making the recesses in the reflecting medium or the reflecting elements of different dimensions but identical shapes.

The result is also obtained by placing the recesses in the reflecting medium or the reflecting elements over a uniform or nonuniform grid.

The result is also obtained by making the set of the discrete elements followed by coating the hologram carrier plate with a transparent for the reading radiation layer. This coating layer provides a phase shift of the reading radiation by a specified value; a set of holes is made in the layer, shapes, dimensions and locations of these holes are calculated in the following way: the amplitude in each of the hologram elements is determined, then its mean value over the entire hologram is determined; then the obtained mean value is subtracted from the initial values, and in the areas where the difference is negative, holes are made while all negative amplitude values obtained after the subtraction are assigned positive values that are equal by modulus.

The result is also obtained by transforming the digital hologram pattern into a digital pattern of the restored layout image and by comparing it with the pattern of the initial layout image. Then a measure of discrepancy is selected, a comparison according to this measure is performed and its results are used to correct the digital hologram pattern.

The result is also obtained by multiple comparisons according to the selected measure and multiple corrections.

The result is also obtained if the measure of discrepancy is selected as the maximum difference of intensities or amplitudes in dots with identical coordinates in the initial layout pattern and in the one virtually restored in a digital form from the digital hologram pattern.

The result is also obtained if the measure of discrepancy is selected as a sum of modules of differences of intensities or amplitudes in all dots of the initial layout pattern and of the one virtually restored in a digital form from the digital hologram pattern.

The result is also obtained if the measure of discrepancy is selected as a sum of squares of differences of intensities or amplitudes in all dots of the initial layout pattern and of the one virtually restored in a digital form from the digital hologram pattern.

The result is also obtained if the measure of discrepancy is selected as a sum of fixed powers of differences of intensities or amplitudes in all dots of the initial layout pattern and of the one virtually restored in a digital form from the digital hologram pattern.

The result is also obtained by using a method of local variations to correct the digital hologram pattern.

The result is also obtained by using any of gradient methods to correct the digital hologram pattern.

The result is also obtained by transforming the digital hologram pattern into a digital pattern of the restored layout image and by comparing it with the pattern of the initial layout image. Then a measure of discrepancy is selected, a comparison according to this measure is performed and its results are used to correct the digital pattern of the calculated diffraction picture

The result is also obtained by multiple comparisons according to the selected measure and multiple corrections.

The result is also obtained if the measure of discrepancy is selected as a maximum difference of intensities or amplitudes in dots with identical coordinates in the initial layout pattern and in the one virtually restored in a digital form from the digital hologram pattern.

The result is also obtained if the measure of discrepancy is selected as a sum of modules of differences of intensities or amplitudes in all dots of the initial layout pattern and of the one virtually restored in a digital form from the digital hologram pattern.

The result is also obtained if the measure of discrepancy is selected as a sum of squares of differences of intensities or amplitudes in all dots of the initial layout pattern and of the one virtually restored in a digital form from the digital hologram pattern.

The result is also obtained if the measure of discrepancy is selected as a sum of arbitrary powers of differences of intensities or amplitudes in all dots of the initial layout pattern and of the one virtually restored in a digital form from the digital hologram pattern.

The result is also obtained by using a method of local variations to correct the digital pattern of the calculated diffraction picture.

The result is also obtained by using any of gradient methods to correct the digital pattern of the calculated diffraction picture.

The result is also obtained by transforming the digital hologram pattern into a digital pattern of the restored layout image and by comparing it with the pattern of the initial layout image. Then a measure of discrepancy is selected, a comparison according to this measure is performed and its results are used to correct the digital pattern of the initial layout image.

The result is also obtained by multiple comparisons according to the selected measure and multiple corrections.

The result is also obtained if the measure of discrepancy is selected as a maximum difference of intensities or amplitudes in dots with identical coordinates in the initial layout pattern and in the one virtually restored in a digital form from the digital hologram pattern.

The result is also obtained if the measure of discrepancy is selected as a sum of modules of differences of intensities or amplitudes in all dots of the initial layout pattern and of the one virtually restored in a digital form from the digital hologram pattern.

The result is also obtained if the measure of discrepancy is selected as a sum of squares of differences of intensities or amplitudes in all 10 dots of the initial layout pattern and of the one virtually restored in a digital form from the digital hologram pattern.

The result is also obtained if the measure of discrepancy is selected as a sum of arbitrary powers of differences of intensities or amplitudes in all dots of the initial layout pattern and of the one virtually restored in a digital form from the digital hologram pattern.

The result is also obtained by using a method of local variations to correct the digital pattern of the initial layout image.

The result is also obtained by using any of gradient optimization methods to correct the digital pattern of the initial layout image.

### DETAILED DESCRIPTION

Building a hologram as a set of discrete elements that differ by their optical characteristics makes it possible—similar to the prior art device (prototype)—to generate binary holograms producing high-quality images. And a resolution capability of synthesized binary holograms fully corresponds to the classic diffraction theory: the angular diameter has a value about a ratio between the wavelength of an illuminating light or a monokinetic corpuscular beam and the overall dimensions of the hologram, and therefore it can be higher than that of traditional optical elements.

Thus it becomes possible to use received binary holograms for generating images on a sensitive to used radiation material that allows to go without any focusing or other traditional optical elements for transforming wave fronts between the hologram, which contains an information about an image in the form of a set of elements of proper dimensions made on the substrate, and a plate coated by the sensitive to the used radiation material; and the holographic image generated on the plate is defined by locations and shapes of the hologram elements, by the relative positions of the hologram and the plate as well as by parameters of the reading radiation, in particular by its frequency content (wavelength) and wave front shape, which in their turn are determined by the radiation source and, if necessary by a special system that shapes the beam. Besides, the volume of the information contained in the hologram coincides with the volume in the image created at the hologram restoration that makes it possible to precalculate the necessary hologram dimensions, structure and time of its production.

To increase the contrast of the restored layout image and to significantly reduce its dimensions compared to the initial one, the initial layout is transformed into a digital pattern. Then the amplitude and phase information, which characterizes each dot of the pattern as an extended or point radiator is recorded and the parameters necessary for the recording radiation beam are calculated. To do so, elements of the digital pattern of the layout image are transformed into a digital pattern of a future hologram. A diffraction picture in each dot of the future hologram created by the whole group of radiators—elements of the digital pattern of the layout image is determined and then an interference picture is calculated. This interference picture is a result of interaction of the calculated diffraction picture and the calculated wave front from a virtual reference point or extended radiation source identical to the reversed real wave front of the source, which will be used for generation of the holographic image of the layout. The obtained result is used as a signal for modulating the radiation beam used to get a diffraction structure of the hologram on its carrier plate.

The transformation of the initial layout into the digital pattern and recording the amplitude and phase information that characterizes each dot of the pattern as an extended or point radiator, allows to calculate the diffraction picture produced by the layout as a sum of diffraction pictures made by all its elements employing the previously known solution of the diffraction problem (electromagnetic waves propagation) for the above-mentioned extended or point radiator.

The conversion of elements of the digital pattern of the layout image into the digital pattern of the future hologram and calculations of the diffraction picture in each dot of the future hologram generated by the whole group if the radiators-elements of the digital pattern of the layout image makes it possible to get the wave front from the given layout (called “object”). This wave front depends only on the given layout itself and the method of its illumination assumed at the calculation of the diffraction picture and does not depend on an amplitude or an amplitude distribution, a phase or a phase distribution and a position of the reference radiation source. That is why one and the same received object wave front can be used to calculate a number of holograms with different restoration beams and various optical schemes.

The calculation of the interference picture received by an interaction of the calculated diffraction picture and the calculated wave front from a virtual reference point or extended radiation source identical to the reversed real wave front of the source, which will be used for generation of the holographic image of the layout is necessary to get a function of optical property distributions over the hologram, for example of transmission or reflection abilities.

In various embodiments the set of discrete elements is accomplished as holes in an opaque or transparent medium depending on the required type of the hologram to be generated—an amplitude or a phase one.

In various embodiments the holes are made of the same dimensions and shapes. It provides the quickest and most precise fabrication of this set of holes because of its technological advantages at using state-of-the-art equipment (electronic lithography sets, in particular). Besides, the calculation process becomes simpler and quicker since it is enough to solve the task of radiation diffraction on the hole of the selected shape only once.

In various embodiments the holes are made of various dimensions but of one and the same shape. It allows simplifying and accelerating the calculation process since it is enough to solve the task of radiation diffraction on a hole of the selected shape only once.

It is advisable to place the holes over a uniform or nonuniform grid. It is necessary to provide the best approximation (transmission) of the produced by the hologram information contained in the calculated digital pattern of the future hologram.

In various embodiments the set of discrete elements is made as alternate recesses in the reflecting medium or alternate reflecting and non-reflecting elements. It allows enlarging the bank of technological devices that can be used for producing holograms.

Making the recesses in the reflecting medium or reflecting elements of one and the same dimensions and shapes or different dimensions but one and the same shape is necessary—as in the case with the holes—for the quickest and most precise fabrication of the whole set of holes, simplifying and accelerating the process.

As in the case with the holes, it is advisable to place the recesses over a uniform or nonuniform grid. It provides the best approximation (transmission) of the produced by the hologram information contained in the calculated digital pattern of the future hologram

Coating the hologram carrier plate already containing the required set of discrete elements with a layer of a transparent for the restoring radiation material, which provides a required phase shift of the restoring radiation, is necessary for making a preform that permits the amplitude hologram to be transformed into an amplitude-phase hologram.

Making a set of holes having calculated shapes, dimensions and locations in the transparent for the restoring radiation material provides forming the phase part of the created amplitude-phase hologram.

In order to account for an effect of the phase part of the hologram on its amplitude part and re-calculate properly the hole distribution on the hologram, it is necessary to determine the amplitude in each of the hologram elements, to determine its mean value over the entire hologram, to subtract the obtained mean value from the initial values, and to assign the modulus equal positive values to all negative amplitude values obtained after the subtraction.

The described procedure makes it possible to get a hologram having higher diffraction efficiency and able to realize a doubled dynamic bandwidth that on the whole allows to restore a given layout more precisely; and this is achieved by using relatively simple technological operations.

The transformation of the digital hologram pattern into the digital pattern of the restored layout image and its comparison with the pattern of the initial layout image, selection of the discrepancy measure, its use for the comparison and correction of the digital hologram pattern based on the results obtained during the comparison allows to evaluate and increase the layout quality by the calculations, with no experiments.

It is advisable to perform the comparison based on the selected measure and subsequent corrections more than once. It provides a possibility of receiving the layout of any previously specified image from among feasible ones, which has the accuracy required by technological peculiarities.

In various embodiments the selected discrepancy measure is the maximum difference of intensities or amplitudes in dots with identical coordinates in the initial layout pattern and in the one virtually restored in a digital form from the digital hologram pattern. It allows direct estimation of the most local deviation of the restored image from the given one, i.e. the accuracy of reproduction of small details.

If the measure of discrepancy is selected as a sum of modules of differences of intensities or amplitudes in all dots of the initial layout pattern and of the one virtually restored in a digital form from the digital hologram pattern, it allows the necessary calculations to be simplified and accelerated, since this measure is one of the most simply and quickly calculated, and at the same time an estimation of a discrepancy degree between the restored and the given layouts can be performed with a sufficient accuracy.

A sum of squares of differences of intensities or amplitudes in all dots of the initial layout pattern and of the one virtually restored in a digital form from the digital hologram pattern can also be used as the measure of discrepancy. In this case calculations based on gradient methods are simplified and accelerated since this measure is the most analytically convenient.

A sum of arbitrary powers of differences of intensities or amplitudes in all dots of the initial layout pattern and of the one virtually restored in a digital form from the digital hologram pattern can also be used as the measure of discrepancy. Its employment makes it possible to vary and to select an accuracy of estimation of approximation quality of the restored and the given layouts as well as an accuracy of reproduction of small parts.

The method of local variations used to correct the digital hologram pattern allows the correction procedure to be automatic.

In the latter case, as the conducted studies showed, it is possible to apply any of the gradient methods of optimization for the correction of the digital hologram pattern. An advantage of their usage is that the calculation procedure is considerably accelerated compared with the method of local variations and other methods, which do not calculate derivations.

One more embodiment is possible where the digital hologram pattern is transformed into the digital pattern of the restored layout image and is compared with the initial layout pattern, then a measure of discrepancy is selected and the obtained results are used to correct the digital pattern of the calculated diffraction picture but not the digital hologram pattern, as described above. Advantages of such transformation lie in a possible usage of the determined in this way diffraction picture for calculating holograms for different sources of the reference radiation.

For this embodiment, as well as for another exemplary embodiment, some special peculiarities are possible. Among them there are multiple corrections according to the selected comparison measure; employment of such measures of discrepancy as the maximum difference of intensities or amplitudes in dots with identical coordinates in the initial layout pattern and in the one virtually restored in a digital form from the digital hologram pattern; a sum of modules of differences of intensities or amplitudes in all dots of the initial layout pattern and of the one virtually restored in a digital form from the digital hologram pattern; a sum of squares of differences of intensities or amplitudes in all dots of the initial layout pattern and of the one virtually restored in a digital form from the digital hologram pattern; a sum of arbitrary powers of differences of intensities or amplitudes in all dots of the initial layout pattern and of the one virtually restored in a digital form from the digital hologram pattern; as well as employment of such ways of correcting the digital pattern of the calculated diffraction picture as the method of local variations or any gradient method.

One more embodiment is possible where the digital hologram pattern is transformed into the digital pattern of the restored layout image and is compared with the initial layout pattern, then a measure of discrepancy is selected and the obtained results are used to correct the digital pattern of the initial layout image but not the digital hologram pattern or the digital pattern of the calculated diffraction picture as described above. Advantages of such transformation are as follows: firstly, it is possible to use the ready initial layout image with the correction provided for the projection lithography; secondly, it is possible to use existing ways of correction and the appropriate ready software provided for the projection lithography; thirdly, a number of corrective steps is reduced since the quantity of elements of the initial layout image to be corrected is much less (in hundreds of time) than the quantity of such elements in the hologram.

For this embodiment, as well as for other exemplary embodiments, some special peculiarities are possible. Among them there are multiple corrections according to the selected comparison measure; employment of such measure of discrepancy as the maximum difference of intensities or amplitudes in dots with identical coordinates in the initial layout pattern and in the one virtually restored in a digital form from the digital hologram pattern; employment of such measure of discrepancy as a sum of modules of differences of intensities or amplitudes in all dots of the initial layout pattern and of the one virtually restored in a digital form from the digital hologram pattern; employment of such measure of discrepancy as a sum of squares of differences of intensities or amplitudes in all dots of the initial layout pattern and of the one virtually restored in a digital form from the digital hologram pattern; employment of such measure of discrepancy as a sum of arbitrary powers of differences of intensities or amplitudes in all dots of the initial layout pattern and of the one virtually restored in a digital form from the digital hologram pattern; as well as employment of such ways of correcting the digital pattern of the initial layout image as the method of local variations or any gradient method.

Various aspects of the claimed method are illustrated by the following examples:

### EXAMPLE 1

In the most general case the method is embodied as follows. An initial layout, for instance an image of an integrated circuit or a topology is transformed into a digital pattern. The transformation is performed as follows: the initial layout in a black-and-white form is placed in a certain coordinate system. In one embodiment the image may be two-tone, when the image consists for example of white elements on a black background, and in the general case—halftone, when the image consists of parts having one of a previously specified quantity of brightness level, for instance from 0 to 255. Then a fine grid with a previously specified pitch is placed in the same coordinate system. For each node of the grid within the area covered by the layout, coordinates of the node and a brightness of the layout in the point are recorded. If it is required to reproduce the layout with a specified distribution of the radiation phase over this layout, then this phase distribution is also presented as a black-and-white image or in a general case—as a halftone image, and is also placed in the same coordinate system. An enumeration of the following four parameters—the two coordinates, the brightness and the phase for all nodes of the grid, which are in the area covered by the initial layout,—presented for example as a list, a vector or a matrix is a pattern in a digital form. Thus the amplitude information and the phase data that characterize each dot of the pattern as a point radiator are recorded. If it is required to present each dot of the pattern as an extended radiator, for example a circuit or a square, then the coordinates of this dot are considered to be the coordinates of the extended radiator center; the dot brightness is considered to be the brightness in the center of the extended radiator, and the phase of the dot is considered to be the phase in the center of the extended radiator and additionally a shape of the extended radiator, and amplitude and phase distributions over its surface are specified. Then a diffraction picture in each dot of the future hologram is calculated; it is created from the whole set of radiators—elements of the digital pattern of the layout image. A personal computer provided with the appropriate software is used for this purpose. Later on there are performed calculations of an interference picture, which will be obtained as a result of interaction of the calculated diffraction picture with the calculated wave front from a virtual reference radiation source identical to the reversed wave front of the real source, which will be further used to restore the image recorded by the hologram. The received data is used to modulate the radiation beam employed to record the hologram on its carrier plate. Lasers or sources of accelerated particles may be used as this source since under their effect there might be a change of properties of certain areas of the illuminated carrier. The latter may be a photoresist of any type sensitive to the used radiation.

### EXAMPLE 2

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

The obtained data were used to modulate the radiation beam employed to record the hologram on its carrier. The hologram carrier was a chromium layer of 0.1 μm thickness deposited on a transparent substrate and coated by a layer of the ERP-40 electronic resist of 0.4 μm thickness, which was exposed in the ZBA-21 e-beam lithographer. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 3

The method is realized in the same way as described in Example 2 with one exception that after the elimination of the illuminated areas of the chromium from the carrier plate, the gaps formed in the chromium are filled with a dye that absorbs the radiation used to restore the holographic image.

### EXAMPLE 4

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then an amplitude value in each point of the hologram was calculated, its mean value over the entire hologram was determined and the obtained mean value was subtracted from the initial values; and in order to make phase-correctng holes, the shape, dimensions and locations of those areas where the difference was negative were stored and all negative amplitude values obtained after the subtraction were assigned positive values that were equal by modulus.

The obtained data were used to modulate the radiation beam employed to record the hologram on its carrier. The hologram carrier was a chromium layer of 0.1 μm thickness deposited on a transparent substrate and coated by a layer of the ERP-40 electronic resist of 0.4 μm thickness, which was exposed in the ZBA-21 e-beam lithographer. After the hologram was recorded as a set of discrete elements, the electronic resist and the chromium were successively processed to eliminate the illuminated areas.

When the set of discrete element was ready, the hologram carrier plate was covered with a layer of a transparent for the restoring radiation material that provided a phase shift of the restoring radiation by a given value; this layer had phase-correcting holes, the shape, dimensions and location were already calculated as mentioned above. The phase-correcting holes were made in the same way as the hologram recording.

The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 5

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then the image to be restored from the digital hologram pattern, which created by the method described above, was calculated.

The calculations were performed in the following way:
computation of the complex amplitude of the radiation provided by the restoring source in each dot of the hologram and further addition of this amplitude to the complex amplitude of the digital hologram pattern;
computation of a diffraction picture in each dot of the virtually restored layout created from the whole set of radiators—elements of the digital hologram pattern; a method of calculation of sums of the convolution type using the Fourier transform and the FFT algorithm was employed for this purpose. A personal computer provided with the appropriate software was used for its realization;
computation of the intensity—squared module of the complex amplitude—in each dot of the digital pattern of the virtually restored image.

Then the measure of discrepancy—the maximum difference of intensities in dots with identical coordinates in the initial layout pattern and in the one virtually restored in a digital form from the digital hologram pattern is calculated.

Then the intensity in one dot of the digital hologram pattern was lightly increased and the digital layout pattern was restored once again and the calculation of the above measure of discrepancy was also repeated. If the computed value proved to be less than before, the change in the digital hologram pattern was saved, if not—the intensity in the same dot of the digital hologram pattern was lightly reduced by the same extent, and after that the digital layout pattern was restored once again and the calculation of the above measure of discrepancy was also repeated. If the computed value proved to be less than before, the change in the digital hologram pattern was saved, if not—the intensity value in the same dot of the digital hologram pattern was remained unchanged.

Then this procedure was repeated for all dots of the digital hologram pattern.

The obtained data were used to modulate the radiation beam employed to record the hologram on its carrier. The hologram carrier was a chromium layer of 0.1 μm thickness deposited on a transparent substrate and coated by a layer of the ERP-40 electronic resist of 0.4 μm thickness, which was exposed in the ZBA-21 e-beam lithographer. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 6

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then the image to be restored from the digital hologram pattern, which created by the method described above, was calculated.

The calculations were performed in the following way:
computation of the complex amplitude of the radiation provided by the restoring source in each dot of the hologram and further addition of this amplitude to the amplitude of the digital hologram pattern;
computation of a diffraction picture in each dot of the virtually restored layout created from the whole set of radiators—elements of the digital hologram pattern; a method of calculation of sums of the convolution type using the Fourier transform and the FFT algorithm was employed for this purpose. A personal computer provided with the appropriate software was used for its realization;
computation of the intensity—squared module of the complex amplitude—in each dot of the digital pattern of the virtually restored image.

Then the measure of discrepancy—a sum of modules of intensity differences of all dots of the initial layout pattern and of the one virtually restored in a digital form from the digital hologram pattern was calculated.

Then the intensity in one dot of the digital hologram pattern was lightly increased and the digital layout pattern was restored once again and the calculation of the above measure of discrepancy was also repeated. If the computed value proved to be less than before, the change in the digital hologram pattern was saved, if not—the intensity in the same dot of the digital hologram pattern was lightly reduced by the same extent, and after that the digital layout pattern was restored once again and the calculation of the above measure of discrepancy was also repeated. If the computed value proved to be less than before, the change in the digital hologram pattern was saved, if not—the intensity value in the same dot of the digital hologram pattern was remained unchanged.

Then this procedure was repeated for all dots of the digital hologram pattern

The obtained data were used to modulate the radiation beam employed to record the hologram on its carrier. The hologram carrier was a chromium layer of 0.1 μm thickness deposited on a transparent substrate and coated by a layer of the ERP-40 electronic resist of 0.4 μm thickness, which was exposed in the ZBA-21 e-beam lithographer. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 7

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then the image to be restored from the digital hologram pattern, which created by the method described above, was calculated.

The calculations were performed in the following way:
computation of the complex amplitude of the radiation provided by the restoring source in each dot of the hologram and further addition of this amplitude to the complex amplitude of the digital hologram pattern;
computation of a diffraction picture in each dot of the virtually restored layout created from the whole set of radiators—elements of the digital hologram pattern; a method of calculation of sums of the convolution type using the Fourier transform and the FFT algorithm was employed for this purpose. A personal computer provided with the appropriate software was used for its realization;
computation of the intensity—squared module of the complex amplitude—in each dot of the digital pattern of the virtually restored image.

Then the determined by the above described way the digital hologram pattern and the digital pattern of the virtually restored layout were assumed as initial approximations for the method of local variations. A sum of squares of intensity differences of all dots of the initial layout pattern and of the one virtually restored in a digital form from the digital hologram pattern was taken as the measure of discrepancy. After the mentioned measure of discrepancy became less than a specified value on a certain step of realization of the local variations method, the process of the digital hologram pattern correction considered to be completed.

A chromium layer of 0.1 μm thickness deposited on a transparent substrate and coated by a layer of the ERP-40 electronic resist of 0.4 μm thickness, which was exposed in the ZBA-21 e-beam lithographer, was used as the hologram carrier.. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 8

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then the image to be restored from the digital hologram pattern, which created by the method described above, was calculated.

The calculations were performed in the following way:
computation of the complex amplitude of the radiation provided by the restoring source in each dot of the hologram and further addition of this amplitude to the complex amplitude of the digital hologram pattern;
computation of a diffraction picture in each dot of the virtually restored layout created from the whole set of radiators—elements of the digital hologram pattern; a method of calculation of sums of the convolution type using the Fourier transform and the FFT algorithm was employed for this purpose. A personal computer provided with the appropriate software was used for its realization;
computation of the intensity—squared module of the complex amplitude—in each dot of the digital pattern of the virtually restored image.

Then the determined by the above described way the digital hologram pattern and the digital pattern of the virtually restored layout were assumed as initial approximations for the gradient method of optimization. A sum of the sixth powers of intensity differences in all dots of the initial layout pattern and of the one virtually restored in a digital form from the digital hologram pattern was taken as the measure of discrepancy. After the mentioned measure of discrepancy became less than a specified value on a certain step of realization of the gradient method, the process of the digital hologram pattern correction considered to be completed.

A chromium layer of 0.1 μm thickness deposited on a transparent substrate and coated by a layer of the ERP-40 electronic resist of 0.4 μm thickness, which was exposed in the ZBA-21 e-beam lithographer, was used as the hologram carrier. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 9

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. If it was required to reproduce the layout with a specified distribution of the radiation phase over this layout, then this phase distribution was also presented as a black-and-white image or in a general case—as a halftone image, and was also placed in the same coordinate system. An enumeration of the following four parameters—the two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then the image to be restored from the digital hologram pattern, which created by the method described above, was calculated.

The calculations were performed in the following way:
computation of the complex amplitude of the radiation provided by the restoring source in each dot of the hologram and further addition of this amplitude to the complex amplitude of the digital hologram pattern;
computation of a diffraction picture in each dot of the virtually restored layout created from the whole set of radiators—elements of the digital hologram pattern; a method of calculation of sums of the convolution type using the Fourier transform and the FFT algorithm was employed for this purpose. A personal computer provided with the appropriate software was used for its realization;
computation of the intensity—squared module of the complex amplitude—in each dot of the digital pattern of the virtually restored image.

Then the measure of discrepancy—a sum of modules of intensity differences in all dots of the initial layout pattern and of the one virtually restored in a digital form from the digital hologram pattern was calculated.

Then the amplitude in one dot of the digital pattern of the calculated diffraction picture was lightly increased and the digital layout pattern was virtually restored once again and the calculation of the above measure of discrepancy was also repeated. If the computed value proved to be less than before, the change in the digital pattern of the calculated diffraction picture was saved, if not—the amplitude in the same dot of the digital pattern of the calculated diffraction picture was lightly reduced by the same extent, and after that the digital layout pattern was restored once again and the calculation of the above measure of discrepancy was also repeated. If the computed value proved to be less than before, the change in the digital pattern of the calculated diffraction picture was saved, if not—the amplitude value in the same dot of the digital pattern of the calculated diffraction picture was remained unchanged.

Then this procedure was performed for the phase of the same dot of the digital pattern of the calculated diffraction picture.

Then this procedure was performed for the amplitude and phase in all other dots of the digital pattern of the calculated diffraction picture.

The obtained data—the digital hologram pattern—was used to modulate the radiation beam employed to record the hologram on its carrier. The hologram carrier was a chromium layer of 0.1 μm thickness deposited on a transparent substrate and coated by a layer of the ERP-40 electronic resist of 0.4 μm thickness, which was exposed in the ZBA-21 e-beam lithographer. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

### EXAMPLE 10

An image of sets of various geometric figures (squares, triangles, circles with straight line interconnections) was used as an initial layout. The geometric figures had different dimensions (4-6 mm) and the interconnecting lines had different thickness (1-1.5 mm). The initial layout was transformed into a digital pattern through the following operations. The initial layout as a grayscale image was placed in a certain coordinate system. Then a fine grid with a previously specified pitch was placed in the same coordinate system. For each node of the grid within the area covered by the layout, coordinates of the node and a brightness of the layout in this point were recorded. The phase distribution was also presented as a grayscale image and also placed in the same coordinate system. An enumeration of the following four parameters—two coordinates, the brightness and the phase for all nodes of the grid, which were in the area covered by the initial layout,—presented for example as a list, a vector or a matrix was a pattern in a digital form. Thus the amplitude information and the phase data that characterized each dot of the pattern as a point radiator were recorded. Then a diffraction picture in each dot of the future hologram was calculated; it was created from the whole set of radiators—elements of the digital pattern of the layout image. A method of calculation of sums of the convolution type using the Fourier transform and the FFT algorithm was employed for this purpose. A personal computer provided with the appropriate software was used for its realization. Later on there were performed calculations of an interference picture, which would be a result of interaction of the calculated diffraction picture with the calculated wave front from a virtual reference radiation source identical to the reversed wave front of the real source, which would be further used to restore the image recorded by the hologram. The calculations were made by determining a complex amplitude of the radiation produced by the reference source in each dot of the hologram and subsequent adding this amplitude to the complex amplitude of the calculated diffraction picture.

Then the image to be restored from the digital hologram pattern, which created by the method described above, was calculated.

The calculations were performed in the following way:
computation of the complex amplitude of the radiation provided by the restoring source in each dot of the hologram and further addition of this amplitude to the complex amplitude of the digital hologram pattern;
computation of a diffraction picture in each dot of the virtually restored layout created from the whole set of radiators—elements of the digital hologram pattern; a method of calculation of sums of the convolution type using the Fourier transform and the FFT algorithm was employed for this purpose. A personal computer provided with the appropriate software was used for its realization;
computation of the intensity—squared module of the complex amplitude—in each dot of the digital pattern of the virtually restored image.

Then the measure of discrepancy—a sum of modules of intensity differences in all dots of the primarily specified initial layout pattern and of the one virtually restored in a digital form from the digital hologram pattern was calculated.

Then the intensity in one dot of the digital pattern of the initial layout was lightly increased and the digital layout pattern was virtually restored once again and the calculation of the above measure of discrepancy was also repeated. If the computed value proved to be less than before, the change in the digital pattern of the initial layout was saved, if not—the intensity in the same dot of the digital pattern of the initial layout was lightly reduced by the same extent, and after that the digital layout pattern was restored once again and the calculation of the above measure of discrepancy was also repeated. If the computed value proved to be less than before, the change in the digital pattern of the initial layout was saved, if not—the intensity value in the same dot of the digital pattern of the initial layout was remained unchanged.

Then this procedure was performed for the phase of the same dot of the digital pattern of the initial layout.

Then this procedure was performed for the amplitude and phase in all other dots of the digital pattern of the initial layout.

The obtained data—the digital hologram pattern—was used to modulate the radiation beam employed to record the hologram on its carrier. The hologram carrier was a chromium layer of 0.1 μm thickness deposited on a transparent substrate and coated by a layer of the ERP-40 electronic resist of 0.4 μm thickness, which was exposed in the ZBA-21 e-beam lithographer. After the hologram was recorded as a set of discrete elements, the electronic resist and the chromium were successively processed to eliminate the illuminated areas. The image recorded in the created hologram was restored by means of a radiation source. A PLASMA He-Cd laser having a power of 90 mW and a radiation wavelength of 0.442 μm was used for this purpose. Finally a restored image of the initial layout reduced by 1000 times was obtained; and the characteristic dimension of the geometric figures was 1-1.5 um.

While preferred embodiments of the invention have been shown and described herein, it will be understood that such embodiments are provided by way of example only. Numerous variations, changes and substitutions will occur to those skilled in the art without departing from the spirit of the invention. Accordingly, it is intended that the appended claims cover all such variations as fall within the spirit and scope of the invention.

What is claimed:

1. A method of producing holographic images of a layout, the method comprising:
transforming a layout image into a digital pattern;
recording an amplitude and phase information, which characterizes each dot of the pattern as an extended or a point radiator;
creating a diffraction picture in each dot of the future hologram from the whole set of radiators;
calculating an interference picture resulting from an interaction of the calculated diffraction picture with a calculated wave front of a virtual reference point or extended radiation source, which is identical to a reversed real wave front of a source that will be used to generate a holographic image of the layout;
using the obtained result as a signal for modulating a radiation beam employed for hologram structure formation on its carrier; and
generating the hologram as a set of discrete elements, which differ by their optical properties.

2. A method of producing holographic images of a layout as defined in claim 1, wherein the set of discrete elements is implemented as holes in an opaque or transparent medium.

3. A method of producing holographic images of a layout as defined in claim 2, wherein the holes have identical dimensions and shapes.

4. A method of producing holographic images of a layout as defined in claim 2, wherein the holes have different dimensions but identical shapes.

5. A method of producing holographic images of a layout as defined in claim 2, wherein the holes are located over a uniform or nonuniform grid.

6. A method of producing holographic images of a layout as defined in claim 1, wherein the set of discrete elements is implemented as alternating recesses in a reflecting medium or as alternating reflecting and nonreflecting elements.

7. A method of producing holographic images of a layout as defined in claim 6, wherein the recesses in the reflecting medium or reflecting elements have identical dimensions and shapes.

8. A method of producing holographic images of a layout as defined in claim 6, wherein the recesses in the reflecting medium or reflecting elements have different dimensions but identical shapes.

9. A method of producing holographic images of a layout as defined in claim 6, wherein the recesses in the reflecting medium or reflecting elements are located over a uniform or nonuniform grid.

10. A method of producing holographic images of a layout as defined in claim 1, further comprising after making the set of discrete elements:
coating a hologram carrier plate with a transparent layer of adapted for reading radiation material, which provides a phase shift of the reading radiation by a specified value;
forming a set of holes in the transparent layer, shapes, dimensions and locations of the holes are determined by calculations, comprising:
determining an amplitude value in each element of the hologram;
calculating a mean value of the set of holes over the whole hologram;
subtracting the obtained mean value from initial values, and in the areas, where a difference is negative, the holes are made, while all negative amplitude values obtained after the subtraction are assigned positive values that are equal by modulus.

11. A method of producing holographic images of a layout as defined in claim 1, further comprising:
transforming the digital hologram pattern into a digital pattern of a restored layout image;
comparing the digital pattern with the pattern of the initial layout image;
selecting a measure of discrepancy and using the measure for the comparison; and
correcting the digital hologram pattern according to the results of the comparison.

12. A method of producing holographic images of a layout as defined in claim 11, wherein the comparison according to the selected measure of discrepancy and the correction are made more than once.

13. A method of producing holographic images of a layout as defined in claim 11, wherein the selected measure of discrepancy is the maximum difference of intensities or amplitudes in dots with identical coordinates in the initial layout pattern and in the one virtually restored in a digital form from the digital hologram pattern.

14. A method of producing holographic images of a layout as defined in claim 11, wherein the selected measure of discrepancy is a sum of modules of differences of intensities or amplitudes in all dots of the initial layout pattern and of the one virtually restored in a digital form from the digital hologram pattern.

15. A method of producing holographic images of a layout as defined in claim 11, wherein the selected measure of discrepancy is a sum of squares of differences of intensities or amplitudes in all dots of the initial layout pattern and of the one virtually restored in a digital form from the digital hologram pattern.

16. A method of producing holographic images of a layout as defined in claim 11, wherein the selected measure of discrepancy is a sum of arbitrary powers of differences of intensities or amplitudes in all dots of the initial layout pattern and of the one virtually restored in a digital form from the digital hologram pattern.

17. A method of producing holographic images of a layout as defined in claim 11, wherein a method of local variations is used to correct the digital hologram pattern.

18. A method of producing holographic images of a layout as defined in claim 11, wherein any gradient method of optimization is used to correct the digital hologram pattern.

19. A method of producing holographic images of a layout as defined in claim 1, further comprising:
transforming the digital hologram pattern into a digital pattern of a restored layout image;
comparing the digital pattern with the pattern of the initial layout image;
selecting a measure of discrepancy and using the measure for the comparison; and
correcting the digital pattern of the calculated diffraction picture according to the results of the comparison.

20. A method of producing holographic images of a layout as defined in claim 19, wherein the comparison according to the selected measure of discrepancy and the correction are made more than once.

21. A method of producing holographic images of a layout as defined in claim 19, wherein the selected measure of discrepancy is the maximum difference of intensities or amplitudes in dots with identical coordinates in the initial layout pattern and in the one virtually restored in a digital form from the digital hologram pattern.

22. A method of producing holographic images of a layout as defined in claim 19, wherein the selected measure of discrepancy is a sum of modules of differences of intensities or amplitudes in all dots of the initial layout pattern and of the one virtually restored in a digital form from the digital hologram pattern.

23. A method of producing holographic images of a layout as defined in claim 19, wherein the selected measure of discrepancy is a sum of squares of differences of intensities or amplitudes in all dots of the initial layout pattern and of the one virtually restored in a digital form from the digital hologram pattern.

24. A method of producing holographic images of a layout as defined in claim 19, wherein the selected measure of discrepancy is a sum of arbitrary powers of differences of intensities or amplitudes in all dots of the initial layout pattern and of the one virtually restored in a digital form from the digital hologram pattern.

25. A method of producing holographic images of a layout as defined in claim 19, wherein a method of local variations is used to correct the digital pattern of the calculated diffraction picture.

26. A method of producing holographic images of a layout as defined in claim 19, wherein any gradient method of optimization is used to correct the digital pattern of the calculated diffraction picture.

27. A method of producing holographic images of a layout as defined in claim 1, further comprising:
transforming the digital hologram pattern into a digital pattern of a restored layout image;
comparing the digital pattern with the pattern of the initial layout image;
selecting a measure of discrepancy and using the measure for the comparison; and
correcting the digital pattern of the initial layout image according to the results of the comparison.

28. A method of producing holographic images of a layout as defined in claim 27, wherein the comparison according to the selected measure of discrepancy and the correction are made more than once.

29. A method of producing holographic images of a layout as defined in claim 27, wherein the selected measure of discrepancy is the maximum difference of intensities or amplitudes in dots with identical coordinates in the initial layout pattern and in the one virtually restored in a digital form from the digital hologram pattern.

30. A method of producing holographic images of a layout as defined in claim 27, wherein the selected measure of discrepancy is a sum of modules of differences of intensities or amplitudes in all dots of the initial layout pattern and of the one virtually restored in a digital form from the digital hologram pattern.

31. A method of producing holographic images of a layout as defined in claim 27, wherein the selected measure of discrepancy is a sum of squares of differences of intensities or amplitudes in all dots of the initial layout pattern and of the one virtually restored in a digital form from the digital hologram pattern.

32. A method of producing holographic images of a layout as defined in claim 27, wherein the selected measure of discrepancy is a sum of arbitrary powers of differences of intensities or amplitudes in all dots of the initial layout pattern and of the one virtually restored in a digital form from the digital hologram pattern.

33. A method of producing holographic images of a layout as defined in claim 27, wherein a method of local variations is used to correct the digital pattern of the initial layout image.

34. A method of producing holographic images of a layout as defined in claim 27, wherein any gradient method of optimization is used to correct the digital pattern of the initial layout image.

35. A method of producing holographic images of a layout as defined in claim 3, wherein the holes are located over a uniform or nonuniform grid.

36. A method of producing holographic images of a layout as defined in claim 4, wherein the holes are located over a uniform or nonuniform grid.

37. A method of producing holographic images of a layout as defined in claim 7, wherein the recesses in the reflecting medium or reflecting elements are located over a uniform or nonuniform grid.

38. A method of producing holographic images of a layout as defined in claim 8, wherein the recesses in the reflecting medium or reflecting elements are located over a uniform or nonuniform grid.
